(19) United States
(12) Patent Application Publication
(10) Pub. No.: US 2007/0267690 A1
(43) Pub. Date: Nov. 22, 2007

(54) DMOSFET with current injection

(76) Inventor: Ho-Yuan Yu, Saratoga, CA (US)

Correspondence Address: Ho-Yuan Yu, 19308 Vendura Ct, Saratoga, CA, 95070, US

(21) Appl. No.: 11/803,350

(22) Filed: May 14, 2007

Related U.S. Application Data
(60) Provisional application No. 60/802,026, filed on May 19, 2006.

(51) Int. Cl. H01L 29/76

(52) U.S. Cl. 257/327

(57) ABSTRACT

This invention disclosed a novel method for the reduction the resistance of the drift region by using the minority carrier current injector near the drift region. This current injector is a p-n junction or a p-n junction in connection with a resistor to the gate or the p-n junction in connection with a current limiting device to the gate or a combination of the other devices. The current injecting reduces the chip size especially for the high voltage operations. The deep trench filled with oxide near the current injector is also disclosed as the diverter for redirection of the minority carrier current. The current injectors can also be used to shut off the main current flow of the DMOSFET during reverse bias and injecting minority carriers in the forward bias.

### CROSS REFERENCE TO RELATED APPLICATIONS

This application claims priority from U.S. Provisional Patent Application No. 60/802,026 filed May 19, 2006 and entitled “DMOSFET with Current Injection”. The provisional application is herein incorporated by reference.

### BACKGROUND OF THE INVENTION

1. Field of the Invention

This invention relates to the general construction of DMOSFET with innovative device concept and device structures of the current injector of minority carriers for the reduction of on resistance. The current injector achieves the advantage of super junction with much lower production cost.

2. Description of the Related Art

U.S. Pat. No. 5,216,275 Chen disclosed the coolmos or super junction concept by using alternating n-p vertical stripes for sustaining the high voltage and in the mean time reducing the forward voltage drop by injection of charge carriers from the alternating n-p-stripes thus up to 4-5 x chip size reduction can be achieved. With this concept, many patent disclosures have been published since then. U.S. Pat. No. 6,097,063 Fujihara disclosed multiple horizontal layers of n-p structure in the drift region for high voltage sustaining. U.S. Pat. No. 6,294,818 Fujihira disclosed the parallel-stripe type semiconductor device. U.S. Pat. No. 6,528,849 Khemka et al disclosed a dual gate resurf super junction lateral DMOSFET. U.S. Pat. No. 6,586,801 Onishi et al disclosed a semiconductor device having beakdown voltage limiter regions. U.S. Pat. No. 6,639,260 Suzuki et al disclosed a super junction like semiconductor device having a vertical semiconductor element. U.S. Pat. No. 6,700,157 Fujihara disclosed a super junction like semiconductor device. U.S. Pat. No. 6,673,679 Miyasaka et al disclosed the semiconductor device with alternating conductivity type layer and method of manufacturing the same. U.S. Pat. No. 7,042,046 Onishi et al disclosed the super junction semiconductor device and method of manufacturing the same.

### SUMMARY OF THE INVENTION

The objective of this invention is to provide a low cost method for the reduction of the resistance in the DMOSFET drift region by using minority carrier current injection method. The injection of the minority carrier is carried out by a p-n junction near the drift region, the combination of a diode and a resistor for the current limiter, a series of diodes, a combination of the p-n junction and Schottky diodes, a diode with a current limiter of a MOSFET or a JFETs. The current injector can be done by an integrated solution or by the separate components assembled together in a three terminal package. This kind of device can be used for pin to pin replacement with the standard DMOSFETs. The current diverter is disclosed to control the current path inside the drift region when the absolute value of Drain potential is larger than the Source region. The combination of MOSFET and current injector in series is also disclosed with the gate and the current injector in connection or in separation with the current injectors to close the current path in reverse bias.

### BRIEF DESCRIPTION OF THE DRAWINGS

FIG. 1 shows three kinds of Figures. FIG. 1A is a standard MOSFET. FIG. 1B indicated a current injector located near the drift region. FIG. 1C indicated a current injector with a series of resistor for the current limiter.

FIG. 2 shows three kinds of Figures. FIG. 2A indicates a p-n diode and a Schottky diode to be used as the current injector in parallel connection. FIG. 2B shows the series of multiple p-n junctions as the injector. FIG. 2C shows a p-n diode and in series of a current limiter of MOSFET or JFET.

FIG. 3 shows a standard power MOSFET cell of prior art.

FIG. 4 shows a standard power MOSFET cell with a current inject at one side of the gate.

FIG. 5 shows a standard power MOSFET cell with current injector at the drift region.

FIG. 6 shows a cross section of a trench power MOSFET cell of prior art.

FIG. 7 shows a cross section of a trench power MOSFET cell with the current injector below the trench under the gate.

FIG. 8 shows a lateral DMOS cell with current injector located in the drift region.

FIG. 9 shows a deep trench insulator of the current diverter to direct the minority current injection into the drain and source region of a power MOSFET with current injector.

FIG. 10 shows the analysis of current injection into epi layer.

FIG. 11 shows a combination of gate and the current injectors of a trench power MOSFET cell.

FIG. 12 shows the separation of MOSFET and the current injectors of a trench power MOSFET cell.

### DETAILED DESCRIPTION OF THE PREFERRED EMBODIMENT

### Embodiment One

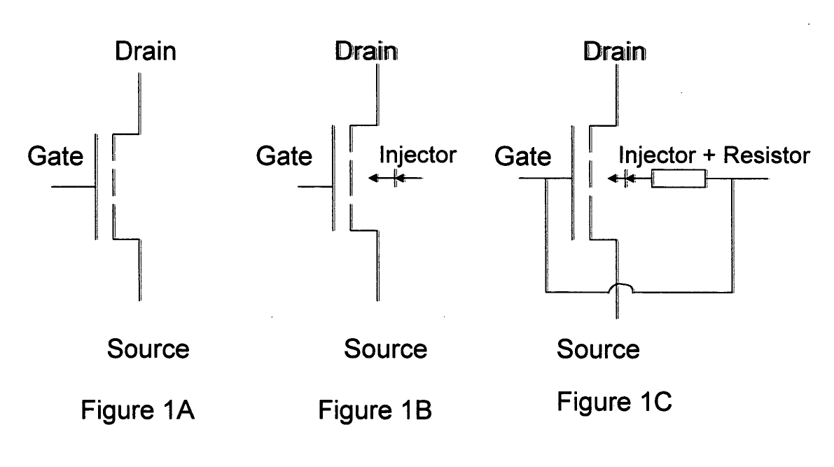

FIG. 1A is a circuit diagram of a simple MOSFET. Gate controls the channel region between source and drain. A draft region is located between the channel region and the drain region. The drift region is used to sustain high drain voltage when the device is in reverse bias. FIG. 1B is a current injector located in the drift region. This current injector is a common p-n junction. When the injector is forward biased to source and drain region, the minority carriers are injected into the drift region, thus the resistance between the drain and source is reduced. In order to connect the current injector to the gate and a resistor is added in series of the injector to limit the injection current.

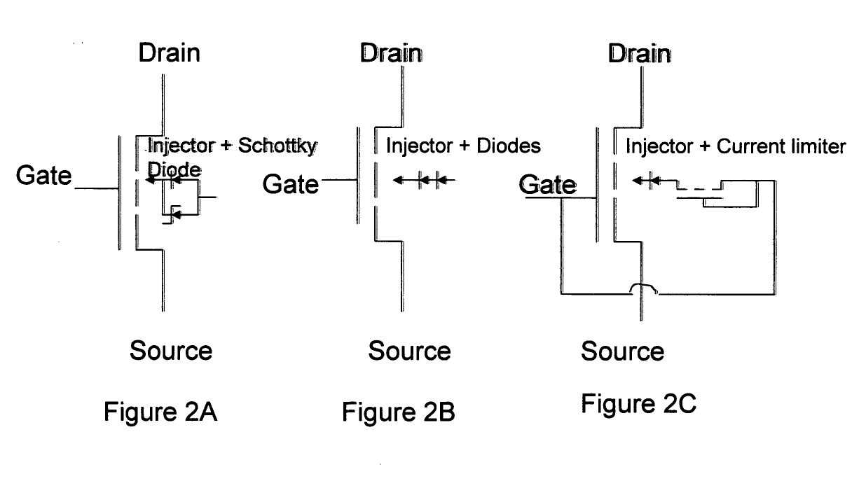

FIG. 2A shows the parallel of a p-n junction and a Schottky diode as the current injector. The purpose of the Schottky diode is to improve the speed of the injector. In order to limit the current, multiple diodes in series connection are illustrated in FIG. 2B. A current limiter such as MOSFET or JFET in series with the current injector is shown in FIG. 2C.

### Embodiment Two

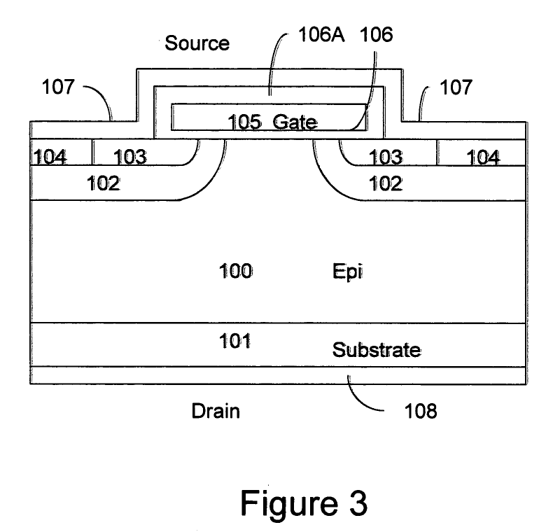

FIG. 3 shows a standard MOSFET cell in the prior art. A semiconductor heavily doped substrate 101 has its epitaxial layer 100 on the top. The epitaxial layer 100 is deposited either by a single layer or multiple layers with various doping concentrations and thicknesses with the same polarity as the substrate. The dielectric layer 106 on the top of the epitaxial layer 100 is formed by thermal oxidation to be used as the gate oxide and CVD oxide 106A is then deposited around the gate 105 for the isolation and protection of the gate. The gate material 105 is either using doped poly crystal silicon or the combination of silicon and silicide for gate control. Layer 102 is formed with opposite polarity of the epitaxial layer 100 as the base region. The shape or the structure of layer 102 can be in rectangular, square, hexagon, round, stripe or other shapes. The layer 103 is a heavily doped region with the same polarity of the epi layer as the source of the device. The layer 104 is a heavily doped region with the opposite polarity of the epitaxial layer and same polarity as the layer 102. Layer 104 is connected to layer 102 to prevent the floating of the this region 102. Layer 104 shorts together with the layer 103 under the metallization layer 107 to form the source of the MOSFET. Layer 108 is the metallization for the ohmic contact to the drain region. This layer is usually a Ti—Ni—Ag or CrAu metallization system for the soldering purpose. Layer 107 is usually a thick Al layer for the wire bond or Ni—Au layer plated on the top of Al layer for the soldering for the source to the package. The thin region in layer 102 below the gate 105 and gate oxide 106 is the channel region between source layer 103 and epi layer 100. This channel region can be open or closed depending on the bias of the gate. The drift region is located from the channel region via epi layer 100 to the substrate 101. For n-MOSFET, the layer 100 is lightly doped n type, layer 101 is heavily doped n type. Layer 102 is a p type layer, layer 103 is heavily doped n type layer and layer 104 a heavily doped p type. For p MOSFET, the polarity of each layer is opposite to the polarity of n MOSFET.

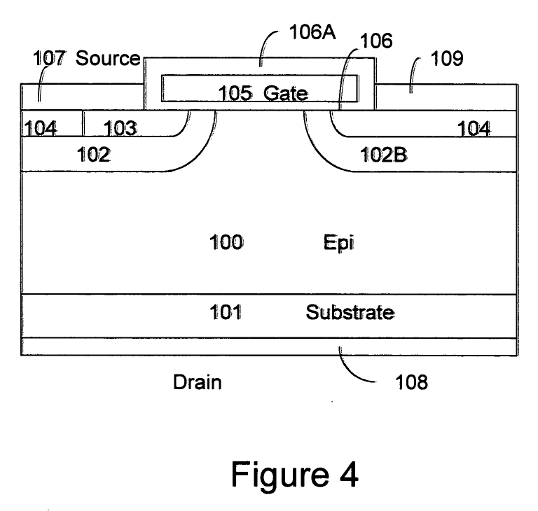

FIG. 4 is similar to FIG. 3 except the region 102B is used as the current injector. Region 102 is separate from source region 107. This layer 102B at the right side is connected to the gate via a heavily doped region 104 a resistor or other current limiters. This resistor is not shown in this Figure and the resistor can be made by a poly layer, diffused layer or other methods. Since the gate voltage is ranging from 4.5V to 10V for most power MOSFETs, therefore a current limiter is required.

Other current limiting device such as the combination of p-n junction and Schottky diode in parallel, a series of multiple p-n diode, as well as current limiting MOSFET or JFECT can also be used. This current limiting device can be integrated to the main MOSFET or using the discrete components assembled into the package as the three terminal device.

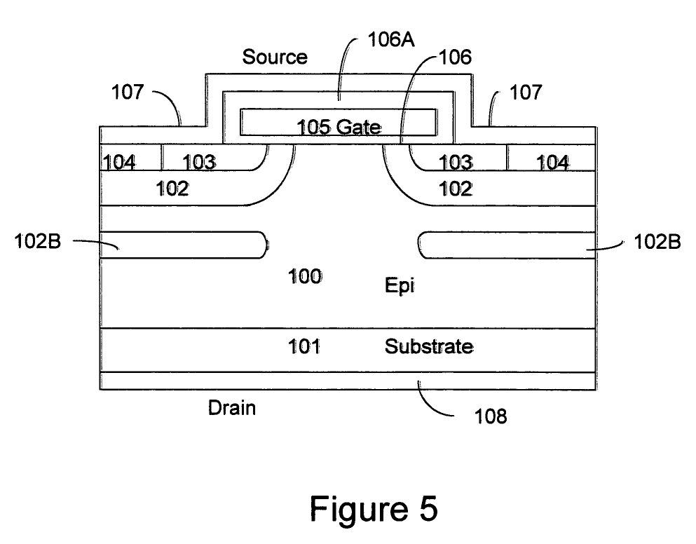

FIG. 5 is similar to the FIG. 3 except a current injector 102B is located under the layer 102. This layer 102B is formed prior to or with the layer 102. The layer 102B is connected to the outside via a current limiting resistor to the gate 105. This configuration can save the chip size of the MOSFET. The distance between 102B and 102 must sustain the voltage since the layer 102B can be forward biased against layer 102. Under reverse bias, layer 102 B can be used to seal off the MOSFET portion so that this 102B can be used to sustain the reverse bias. However, when the MOSFET is switched on, 102B is under forward bias and it will inject minority carriers into the region between 102B and Drain as well as the region above 102B and the MOSFET. Thus the resistance between source and drain Rds(on) can be reduced when the MOSFET is turned on.

### Embodiment Three

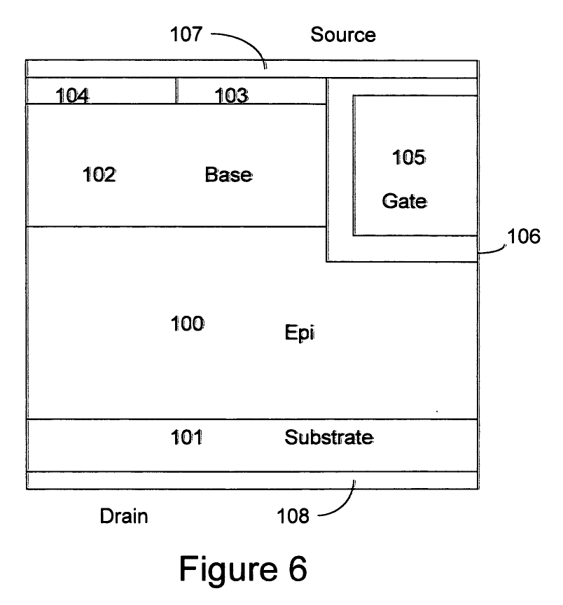

FIG. 6 is the cross section of a trench MOSFET cell as indicated in the prior art. The trench region with layer 106 has the gate oxide layer 106 grown around the edge of the trench. Layer 105 is heavily doped poly silicon or a polycide as the gate. The channel region is along the edge of the gate oxide in the base region 102 which is in the opposite polarity of the epi layer 100. Layer 103 is a heavily doped region with the similar polarity as the epi layer 100. Layer 104 is a heavily doped region with the similar polarity of the layer 102. Metallizatioin layer 107 is formed as the source region with the ohmic contact to the layers 103 and 104. In general the layer 107 is a thick Al layer for wire bond or NiAu plating on the top of Al layer for the soldering. Layer 108 is the metallization for the Drain region for the ohmic contact with layer 101 which is heavily doped substrate with the same polarity of the epitaxial layer 100. Layer 108 can be TiNiAg or CrAu for the soldering of the chip to the package.

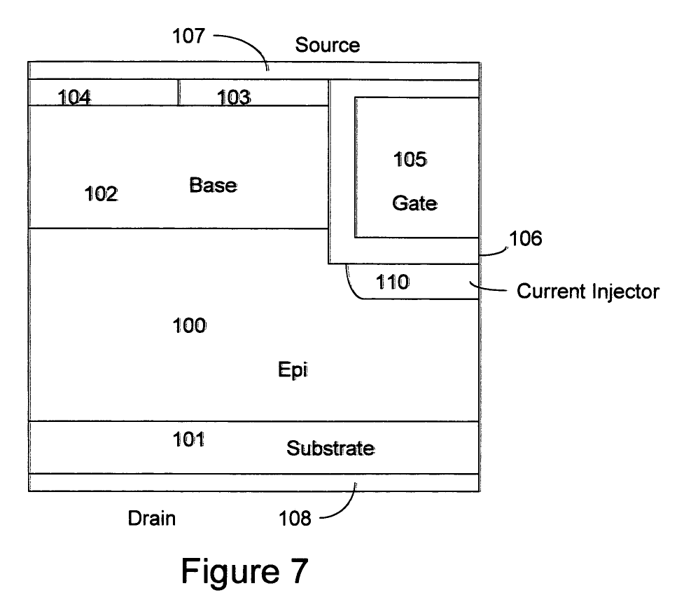

FIG. 7 is similar to FIG. 6 except a current injector 110 is formed below the trench region 106. This 110 layer is an opposite polarity as the epitaxial layer 100 and must keep a safe distance with the layer 102 to sustain the potential difference. The current injector layer 110 is connected to the gate region 105 via a current limiting resistor or other methods, not showing in this Figure. The layer 110 can be used to close the MOSFET region under the reverse bias as an option.

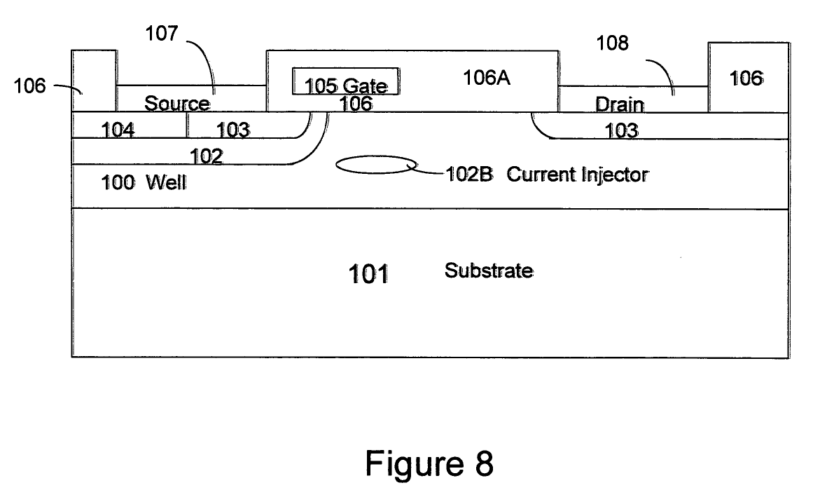

FIG. 8 is a lateral DMOSFET cell structure. The base region 102 is to provide the channel under the gate 105. The base region 102 is in opposite polarity as the well region 100. The well region 100 can be either the opposite polarity of the substrate 101 or the same polarity of substrate 101. The source 103 is a heavily doped region with the same polarity as the well region 100. Region 104 is a heavily doped region with the same polarity as the base region 102 for the ohmic contact of region 102 to the source metallization. The current injector 102B is located near the drift region and has the same polarity as the region 102. The gate 105 is located above the channel with the gate oxide 106. CVD layer 106A is deposited around the gate 105 for the protection and for the isolation of the gate. The Al metallization layer 107 is for the source and layer 108 is for the drain. Under reverse bias, the current inject can block the drift region above and under the injector. For forward bias, the current injector injects the minority carrier into source and drain. The current injector 102B is connected to the gate via a resistor or current limiting device.

### Embodiment Four

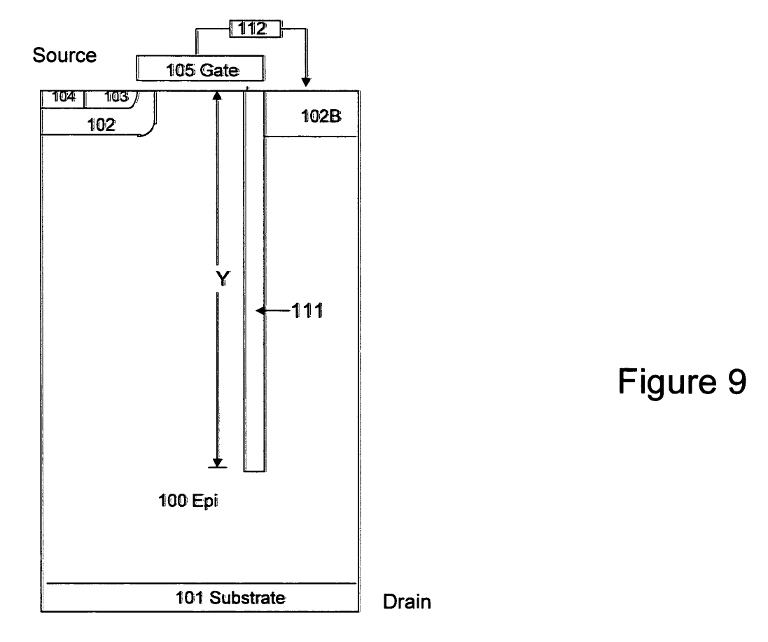

FIG. 9 disclosed a deep trench insulator 111 to direct or divert the current flow between the current injector 102B to the source and drain. The depth of the deep trench isolator, Y, is between 20% to over 95% of the thickness of epi layer 100. The length Y of the diverter determines the minority current flow path. Since the potential of the drain is more positive than the source for the N MOSFET, it is necessary to use this deep trench insulator to redirect the current flow for high voltage MOSFETs, otherwise, the most minority carriers will flow directly toward the source region without this current diverter in this structure. The gate 105 is connected to the injector 102B via a resistor 112.

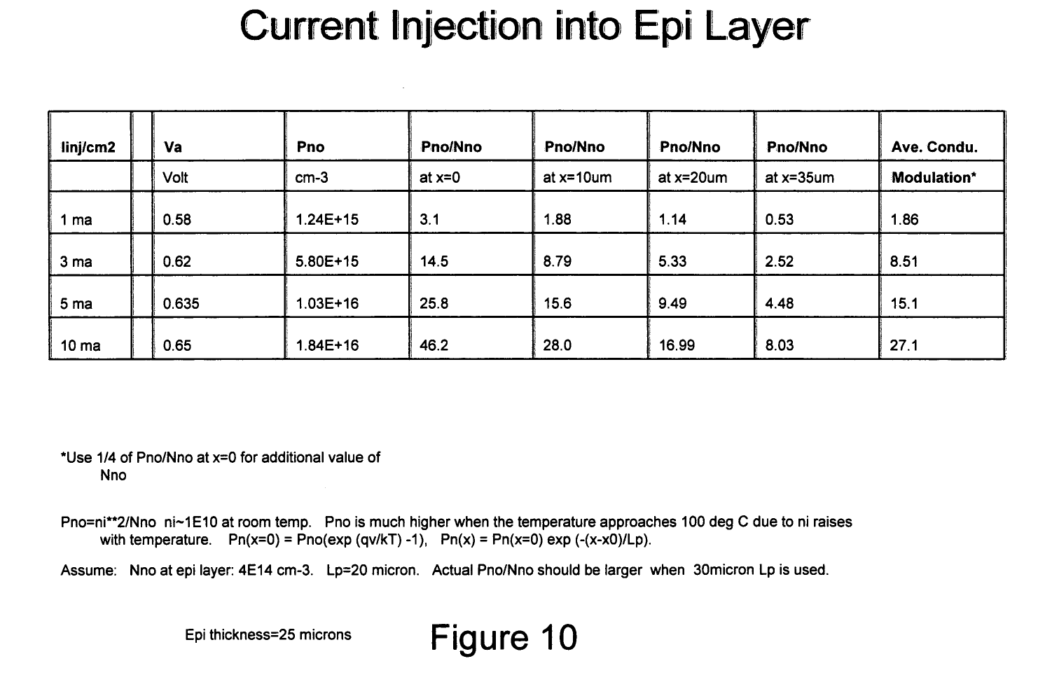

FIG. 10 shows a chart of the minority carrier injection density compared with the doping density of 4E14 cm-3 as the reference. This chart illuminates the effectiveness of the minority carrier injection to the basis resistance of the drift region. The removal of the charge injected into the drift region depends on the effectiveness of the minority current injector. With Schottky diode in parallel with the p-n junction injector can remove the charge quickly and effectively for high speed MOSFETs.

### Embodiment Five

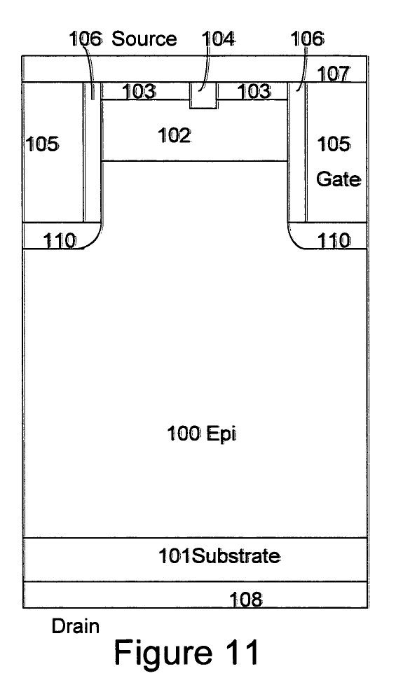

FIG. 11 is a cross section of a Trench MOSFET cell with the current injector located just under the trench. With thin gate oxide, the current injector can be directly connected to the gate. Since the gate potential should be less than one voltage against the drain during the minority injection, the threshold voltage of the MOSFET should be around 0.5 volt. During the reverse bias, as an option the current injectors 110 can close the current path of the Source and Drain if the distance between the injectors is smaller enough. In this FIG. 11, the epi layer 100 of same polarity is deposited on the top of heavily doped substrate 101. The doping concentration and the thickness of the epitaxial layer are depending on the voltage rating of the device. The depth of the trench is from 0.5 um to over 3 microns. After the trench process, the current injectors 110 can be done by either ion implantation or diffusion with the opposite polarity of the epitaxial layer 100. The gate oxide 106 is formed by thermal oxidation either before or after the injector formation. The gate 105 is usually a heavily doped poly or polycide. The base 102 is to provide the conduction layer along the gate depending on the gate bias. Source 103 is a heavily doped region with the same polarity of the epitaxial layer 100 and layer 104 is a heavily doped region with the same polarity of the base 102. Layer 104 is to prevent the floating of the layer 102 under all bias conditions. The purpose of 103 and 104 layers is to form the ohmic contact with the metallization layer 107 for the source. The metallization layer 108 under substrate 101 is for the drain connection. The metallization for the layer 107 is usually an aluminum layer for wire bonding and NiAu layer on the top of aluminum layer for soldering. The metallization for the layer 108 is usually a TiNiAg, CrAu or other metallization for the soldering of the drain to the package. In this structure, as an option the current injectors 110 will close the MOSFET during the reverse bias and open for the MOSFET when the gate and the injector are in forward bias. With proper arrangement, the minority carrier will be injected during forward bias, thus the resistivity of the drift region or Rds(on) or the device will be reduced.

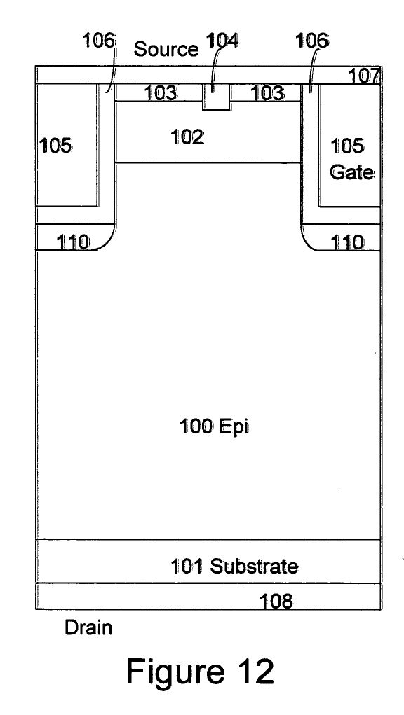

FIG. 12 is similar to the FIG. 11 except the gate and the injector are isolate with different potential. This allows the gate voltage to be higher than 1 volt for better conduction channel control with lower resistance and the gate is connected to the current injector via current limiter device 110. Schottky device can be used at the injector to speed up the switching response.

What is claimed is:

1. A current injector is located near the drift region of the DMOSFET to inject the minority carriers into the drift region in forward bias for the reduction of the drift region resistance under forward bias.

2. This current injector is a p-n junction, a p-n junction connected with a resistor as the current limiter in connection of the gate, multiple p-n junctions as the voltage equalizer connected with the gate voltage, a combination of a p-n junction and a Schottky diode and/or a current limiter, a MOSFET or a JFET as the current limiter in series with a p-n junction injector.

3. A three terminal device that includes a DMOSFET or a power MOSFET with the minority carrier current injector by using discrete components for the current limiter of the injector assembled into the same package. This three terminal device can be used to directly replace the DMOSFET or a power MOSFET.

4. The current injector with current limiter is integrated into the vertical power MOSFET, power DMOSFET, or lateral DMOS in ICs as three terminal device.

5. A semiconductor wafer supporting a plurality of semiconductor structures comprising:
a epitaxial layer of same polarity on the top of the heavily doped semiconductor substrate; an structural of opposite polarity was formed either by implantation with thermal treatment or diffusion. This opposite polarity structure can be formed in stripes, square, round, hexagon, or other shapes. The current injector with the polarity opposite to the epi layer is formed under the base region or use one side of the base region as the current injector. The heavily doped region with similar polarity as the epi layer is located near the edge of the base region of opposite polarity under the gate oxide. The heavily doped region with the opposite polarity as the epi layer is located beside of said of heavily doped region for the ohmic contact to the base region. The gate oxide layer is formed by oxidation, followed by the doped poly layer. After the gate etch, the CVD oxide is deposited. After the opening of the source contact region, the metal is deposited on the top of the wafer. In general, thick Al film is deposited for the wire bond and Ni—Au plating is used on the top of Al film for the soldering of the source plate. The metallization of TiNiAg or CrAu is formed for the ohmic contact at the back of the wafer.

6. The semiconductor wafer of claim 5 has epitaxial layer with single doping concentration and thickness or multiple layers with different thickness or doping concentration depending on the voltage requirements.

7. The semiconductor wafer of claim 5 using the trench structure with the gate oxide is grown on the wall of the trench and deposited heavily doped poly as the gate. The current injector is located under the trench with the opposite polarity as the epi layer and this current injector is connected to the gate with a current limiting resistor or the device such as a series of p-n diodes or current limiter MOSFET or JFET operated at beyond the saturation region. The depth of the trench is ranging from 0.5 micron to over 3 micron.

8. The current injector can be used to shut off the MOSFET at reverse bias to reduce the reverse leakage current of the device as an option.

9. The Schottky device can be used in parallel with the current injector for the reduction of the charge removal of the current injector for fast switching response.

10. Deep trench with oxide fill can be used as the current diverter to redirect the current in order to get good minority carrier coverage. The depth or the length of the deep trench is ranging from 20% of the epitaxial thickness to over 95% of the epitaxial thickness depending on the designs and applications.
